(19) United States
(12) Patent Application Publication
(10) Pub. No.: US 2012/0171867 A1
(43) Pub. Date: Jul. 5, 2012

(54) METHOD FOR FABRICATING FINE PATTERN BY USING SPACER PATTERNING TECHNOLOGY

(75) Inventor: Jin Soo KIM, Icheon-si (KR)

(73) Assignee: HYNIX SEMICONDUCTOR INC., Icheon-si (KR)

(21) Appl. No.: 13/187,581

(22) Filed: Jul. 21, 2011

(30) Foreign Application Priority Data
Dec. 30, 2010 (KR) 10-2010-0138683

(51) Int. Cl. H01L 21/31; H01L 21/311

(52) U.S. Cl. 438/702; 438/763; 257/E21.24; 257/E21.249

(57) ABSTRACT

A method for fabricating a fine pattern includes forming a line-shaped partition pattern on an underlayer, adhering a first spacer to the sides of the partition pattern, dividing the first spacer into two line patterns where one line pattern has one end bent by selectively etching the first spacer portion with a division region, adhering a second spacer, which has a connection protrusion filling the division region and connecting to the partition pattern, to the outer side of the two line patterns, and selectively removing the two line patterns.

### CROSS-REFERENCES TO RELATED APPLICATIONS

The present application claims priority under 35 U.S.C 119(a) to Korean Application No. 10-2010-0138683, filed on Dec. 30, 2010, in the Korean intellectual property Office, which is incorporated herein by reference in its entirety.

### BACKGROUND

Exemplary embodiments of the present invention relate to semiconductor device fabrication, and more particularly, to a method for fabricating a fine pattern by using spacer patterning technology.

The design rule of semiconductor devices is decreasing, and, therefore, the pitch and size of patterns of the devices are also decreasing. Accordingly, a spacer patterning technology (SPT) or a double patterning technology (DPT) is being used as a patterning technology for overcoming a pattern resolution limitation in a photolithography process. If the spacer patterning technology (SPT) is used to form a line and space pattern, it requires a process of dividing the line and connecting a pad-shaped pattern to the divided line.

An SPT process includes a process of forming an additional pattern such as a pad at the end of a line, with the pad having a larger critical dimension (CD) than the line. Thus, the SPT process requires more complex processes. Also, the pitch of the final line patterns formed by the SPT process, that is, the total width of the line and space, becomes one-half as small as the pitch of a partition pattern formed on a wafer by an exposure and etching process, thus making it difficult to form a pattern with a finer CD.

### SUMMARY

An embodiment of the present invention relates to a method for fabricating a fine pattern where a line portion has a fine critical dimension (CD) an end of the line portion that has a larger critical dimension (CD) than the.

In one embodiment, a method for fabricating a fine pattern includes: forming a line-shaped partition pattern on an underlayer; adhering a first spacer to the sides of the partition pattern; dividing the first spacer into two line patterns with one line pattern having a bent end by selectively etching a division region in the first spacer; adhering a second spacer, which has a connection protrusion filling the division region and connecting to the partition pattern, to the outer sides of the two line patterns; and selectively removing the two line patterns.

In another embodiment, a method for fabricating a fine pattern includes: forming a first field region, which defines active regions extending in a first direction, in a cell region of a wafer including the cell region and a peripheral region; forming a hard mask layer on the wafer; forming a line-shaped first partition pattern extending in a second direction crossing the first direction and a second partition pattern covering the peripheral region, on the cell region on the hard mask layer; adhering a first spacer to the side of the first and second partition patterns; dividing the first spacer into two line patterns where one line pattern has a bent end by selectively etching a division region in the first spacer; adhering a second spacer, which has a connection protrusion filling the division region and connecting to the first partition pattern, to the outer sides of the two line patterns; selectively removing the two line patterns; forming a hard mask pattern by selectively removing the hard mask layer portion exposed by the first and second partition patterns and the second spacer; and selectively etching a portion of the active region exposed through the hard mask pattern to form a gate trench for a buried gate at the active region, in which the two line patterns are located, and to form a field trench isolating the active region located at the exposed portion of the outside of the second spacer.

The first and second partition patterns may include a photoresist pattern, and the second spacer may be formed of a material having an etch selectivity with respect to the first spacer, and may include at least one of silicon oxide (SiO₂), silicon nitride (Si₃N₄), and polysilicon.

The first partition pattern may include a line pattern extending in the second direction that crosses the first direction.

The second spacer may be formed of the same material as the partition pattern, and may include at least one of silicon oxide (SiO₂), silicon nitride (Si₃N₄), polysilicon, and other material that has an etch selectivity with respect to the first spacer.

The hard mask layer may be formed to have a single-layer structure or a double-layer structure including at least one of carbon, silicon oxide (SiO₂), silicon nitride (Si₃N₄), polysilicon, and other material that has an etch selectivity with respect to the second spacer, the first partition pattern, and the first spacer.

The adhering of the first spacer to the side of the first and second partition patterns may include: depositing a first spacer layer covering the first and second partition patterns; and anisotropically etching the first spacer layer, wherein the critical dimension of the field trench depends on the deposition thickness of the first spacer layer.

The dividing of the first spacer into the two line patterns may include: forming an etch mask pattern including a hole opening that selectively exposes the first spacer portion adjacent to one of the two edges of the end of the first partition pattern, and a line opening that selectively exposes the first spacer portion adhered to the side of the second partition pattern; and selectively removing the first spacer portion exposed through the etch mask pattern.

### BRIEF DESCRIPTION OF THE DRAWINGS

The above and other aspects, features and other advantages will be more clearly understood from the following detailed description taken in conjunction with the accompanying drawings, in which:

FIG. 1 is a plan view illustrating the arrangement of gates and cell active regions to which a fine pattern fabricating method according to an exemplary embodiment of the present invention is to be applied;

FIGS. 2 to 13 are views illustrating a fine pattern fabricating method according to an exemplary embodiment of the present invention; and

FIGS. 14 and 15 are views illustrating a process of forming an active region and buried gates by applying a fine pattern fabricating method according to an exemplary embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

A fine pattern fabricating method according to an exemplary embodiment of the present invention may be used to fabricate a transistor structure with a buried gate. Accordingly, the transistor structure may have a gate disposed in a gate trench formed in an active region and a gate cap layer formed of a dielectric layer to bury the gate trench to cover the gate located at the bottom of the gate trench.

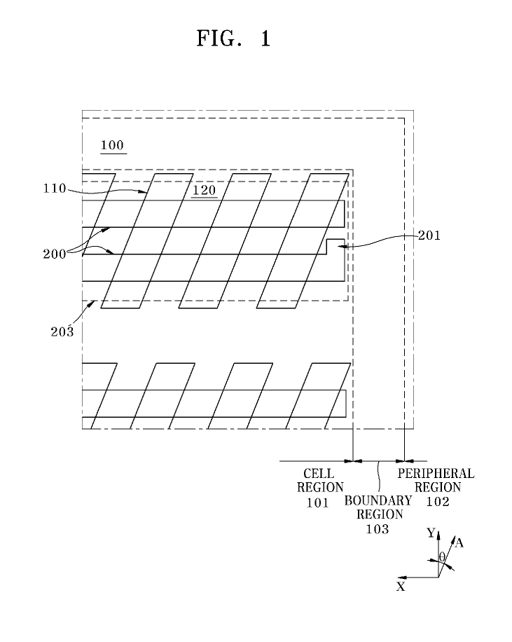

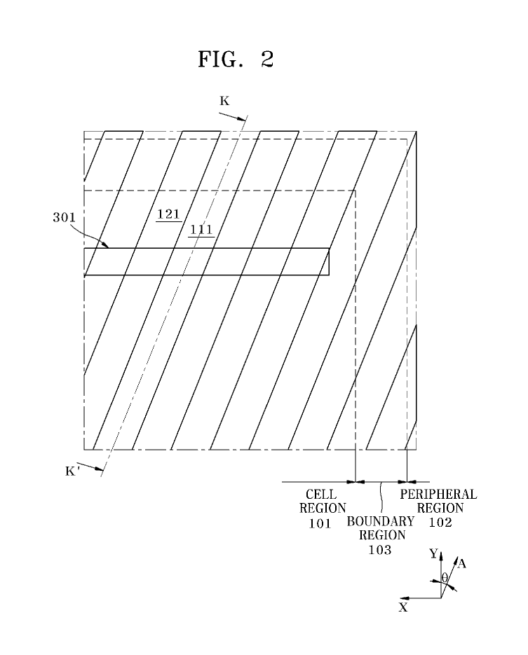

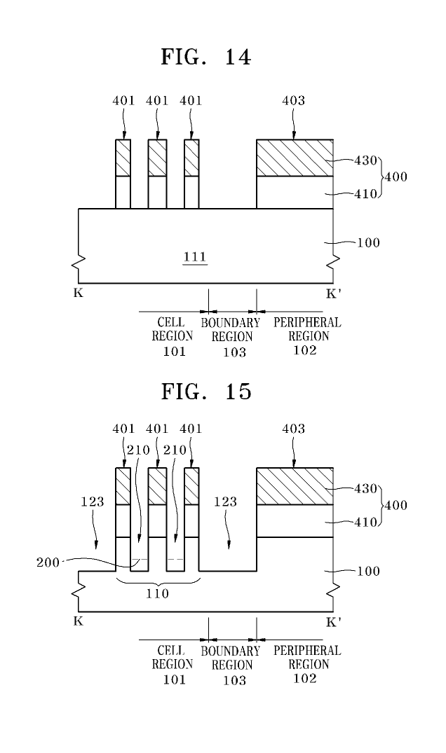

FIG. 1 is a plan view illustrating the arrangement of gates and cell active regions to which a fine pattern fabricating method according to an exemplary embodiment of the present invention is to be applied. FIGS. 2 to 13 are views illustrating a fine pattern fabricating method according to an exemplary embodiment of the present invention. FIGS. 14 and 15 are views illustrating a process of forming an active region and buried gates by applying a fine pattern fabricating method according to an exemplary embodiment of the present invention.

Referring to FIG. 1, cell active regions 110 and a field region 120 with a shallow trench device isolation structure are provided in a cell region 101 of a semiconductor substrate or a wafer 100 that includes the cell region 101, a peripheral region 102, and a boundary region 103 between the peripheral region 102 and the cell region 101. In a DRAM memory device structure where gates 200 are arranged in a line shape in an X-axis direction of an XY coordinate system and bit lines (not illustrated) extend in a Y-axis direction, the cell active region 110 may have a rectangular structure with a major axis extending in an oblique direction A that crosses the X-axis or Y-axis direction at a predetermined angle 8.

Although FIG. 1 illustrates that the cell active regions 110 are arranged in the oblique direction, the cell active region 110 may also have a rectangular structure with a major axis extending in the Y-axis direction. Herein, in order to secure a wider overlay margin at a connection with a connection contact, a line end portion 201 of the gate 200 is bent so that it has a larger critical dimension (CD) than the line and is used as a pad to be connected with the connection contact. While the line end portion is shown as bent at a 90° angle, the invention need not be so limited. The line end may be bent at other angles. Accordingly, the bent direction of the end portion 201 is directed to the line body of the adjacent gate 200. A region 203 covering the two adjacent gates 200 serves as a mask for covering/protecting the gates 200 in a subsequent etching process for defining the cell active region 110.

The fine pattern fabricating method according to an exemplary embodiment of the present invention includes a process of forming a hard mask pattern that defines a field trench for isolating the active region 110 and defines a gate trench for forming a buried gate structure.

Referring to FIG. 2, a first field region 121 defining a first active region 111 extending in a first direction, for example, an oblique direction A crossing the Y-axis direction at a predetermined angle 8 is formed in a cell region 101 of the wafer 100 of FIG. 1. The first active region 111 may extend in a line shape. If the CD of the gate 200 of FIG. 1 is implemented to have a pitch of approximately 10 nm to approximately 20 nm, the active region 110 of FIG. 1 may be patterned through an SPT process or a DPT process because it is difficult to pattern the active region 110 in a rectangular shape due to exposure resolution limitation. In this case, it is primarily patterned in a line shape extending in one direction like the first active region 111.

The reason for this is that it is advantageous in achieving a high pattern resolution when implementing a line and space shape on the wafer 100 through a lithography process, and it can result in a fine pattern smaller than an exposure resolution when using an SPT or DPT process. If the first active region 111 is formed to extend in a line shape, the first active region 111 may be implemented to have a finer critical dimension (CD). A process of forming a field trench for a second field region defining the active region 110 in a rectangular shape may be used by again patterning the first active region 111 in another direction crossing the extending direction.

An exemplary embodiment of the present invention includes a process of forming a hard mask pattern or an etch mask used to form a field trench dividing a line-shaped first active region 111 and a gate trench used to form the gate 200 in a buried gate structure. An exemplary embodiment of the present invention will be described with reference to a plan view and cross-sectional views taken along a line K-K′ extending in the extending direction of the first active region 111 of FIG. 2.

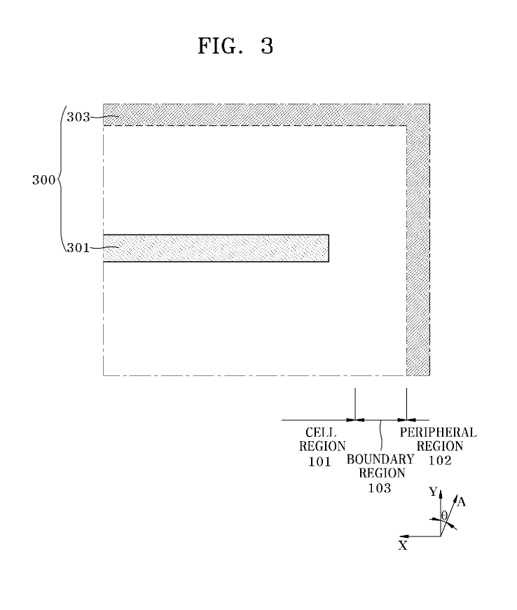

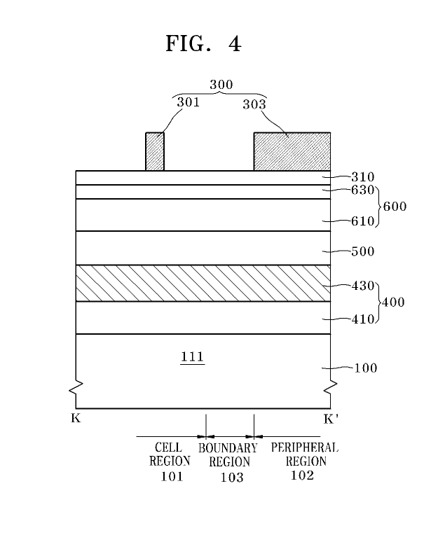

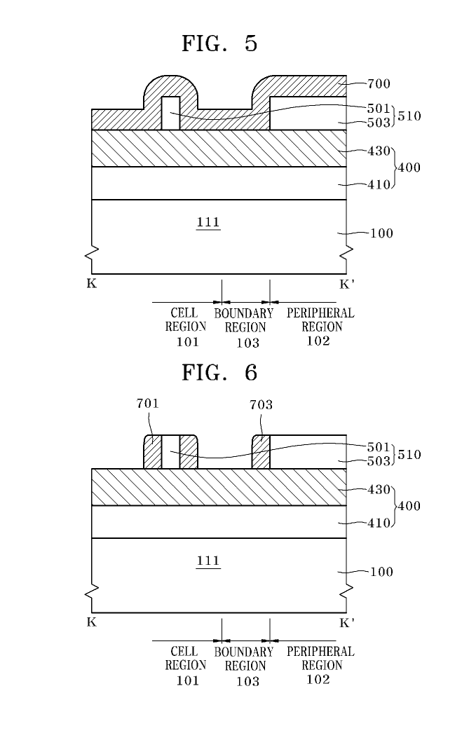

FIGS. 3 and 4 illustrate a process of forming a first photoresist pattern 300 for forming a partition pattern in an SPT process. Referring to FIGS. 3 and 4, a first photoresist pattern 300, which includes a first photoresist first pattern 301 for a partition pattern defined in a line shape on a cell region 101 and a first photoresist second pattern 303 defined in a cell open pattern to expose the boundary region 103 defining the cell region 101 to be SPT-patterned and the boundary of the cell region 101 and to cover the peripheral region 102 not to be SPT-patterned, is formed through a photolithography process.

FIG. 4 shows a first hard mask layer 400, a partition layer 500, and a second hard mask layer 600 are sequentially stacked on a wafer 100. A bottom antireflective layer (BARC) 310 is formed on the second hard mask layer 600. The bottom antireflective layer (BARC) 310 makes it possible to suppress a resolution degradation caused by diffused reflection. The partition layer 500 may be formed of a material having an etch selectivity with respect to the first hard mask layer 400 and the second hard mask layer 600. For example, the partition layer 500 may be formed of a carbon layer, a silicon oxide (SiO₂), a silicon nitride (Si₃N₄), or a polysilicon. The first hard mask layer 400 and/or the second hard mask layer 600 may be a layer formed of carbon, silicon oxynitride (SiON), silicon nitride (Si₃N₄), polysilicon, or other material different from the partition layer 500 in consideration of etch selectivity.

For example, the first hard mask layer 400 may include a double layer of a silicon oxide layer 410 and a silicon nitride layer 430. The second hard mask layer 600 may include, for example, a carbon layer 610 and a silicon oxynitride (SiON) layer 630. The partition layer 500 may include a polysilicon layer 500.

The first photoresist pattern 300 for a partition pattern may be formed to have a pitch three times or larger than the pitch of desired patterns. For example, when the pitch of desired patterns is 10 nm, the first photoresist pattern 300 may be formed to have a 60 nm pitch including a 10 nm CD line and a 50 nm CD space.

Using the first photoresist pattern 300, the second hard mask layer 600 is selectively etched to form a second hard mask pattern. A portion of the partition layer 500 exposed through the second hard mask pattern is selectively etched to form a partition pattern 510 as illustrated in FIG. 5.

Referring to FIG. 5, a partition pattern 510 is formed to resemble the shape of the first photoresist pattern 300. An embodiment of the invention may omit the pattern layer 500 of FIG. 4 or the second hard mask layer 600, and the first photoresist pattern 300 may be used as the partition pattern 510. The partition pattern 510 may include a line-shaped first partition pattern 501 and a second partition pattern 503 covering the peripheral region 102. A first spacer layer 700 is deposited to cover the partition pattern 510.

The first spacer layer 700 may be formed of a material having an etch selectivity with respect to the partition layer 500 and the first hard mask layer 400. For example, the first spacer layer 700 may be formed of silicon oxide (SiO₂), silicon nitride (Si₃N₄), or polysilicon. Herein, the first spacer layer 700 may be deposited to a thickness to have the same CD as the first partition pattern 501.

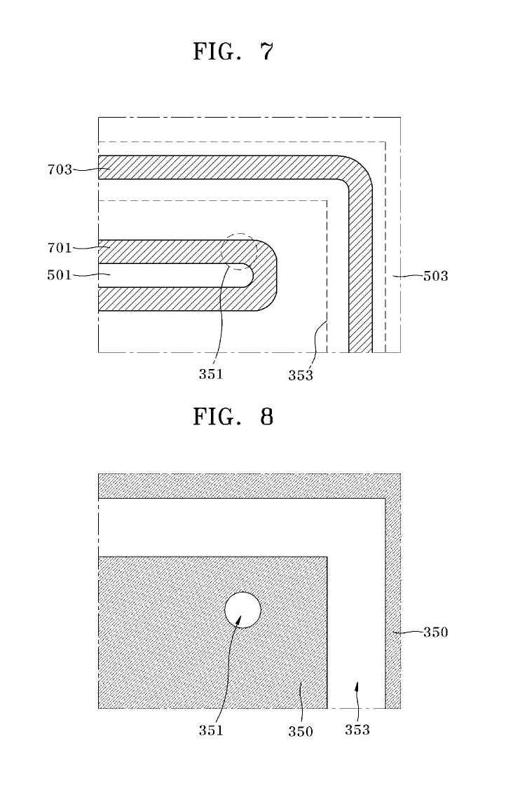

Referring to FIGS. 6 and 7, the first spacer layer 700 is anisotropically etched or spacer-etched, first spacers 701 and 703 are adhered to the side of the partition pattern 510. As can be seen in FIG. 7, the first spacer portion 701 is adjacent to both sides of the first partition pattern 501 and the second spacer portion 703 is adjacent to the second partition pattern 503.

Referring to FIGS. 7 and 8, a second photoresist pattern 350, which has a hole opening 351 exposing a portion of the first spacer portion 701 and a line opening 353 exposing the second spacer portion 703, is formed as an etch mask pattern on the partition pattern 510 and the first spacers 701 and 703. The hole opening 351 is formed to selectively expose a portion of the first spacer portion 701 adjacent to one of two edges of the end of the first partition pattern 501.

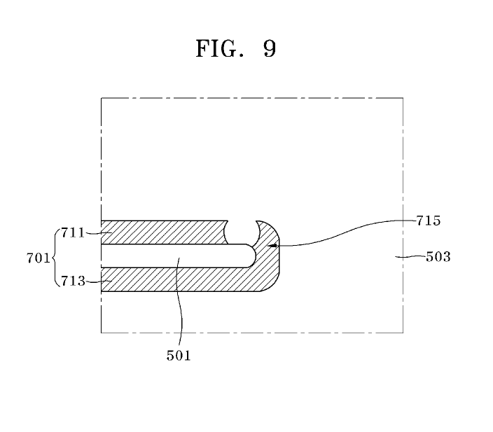

Referring to FIGS. 8 and 9, a portion of the first spacer portion 701 exposed by the second photoresist pattern 350 and the second spacer portion 703 is selectively etched and removed. Accordingly, the first spacer portion 701 is divided into two line patterns 711 and 713 with one end of the line pattern forming a bent portion 715 by selectively etching a portion of the first spacer portion 701 adjacent to one of two edges of the end of the first partition pattern 501. The line pattern 711 has a straight line shape, and the line pattern 713 has an ‘L’ shape with a bent portion 715. The bent portion 715 is formed to provide the bent end portion 201 (i.e., the pad portion of the gate 200 of FIG. 1). Since the end portion of the line pattern 713 has an L-shaped bent portion 715, it is possible to omit the patterning and depositing an additional layer for the pad portion of the gate 200.

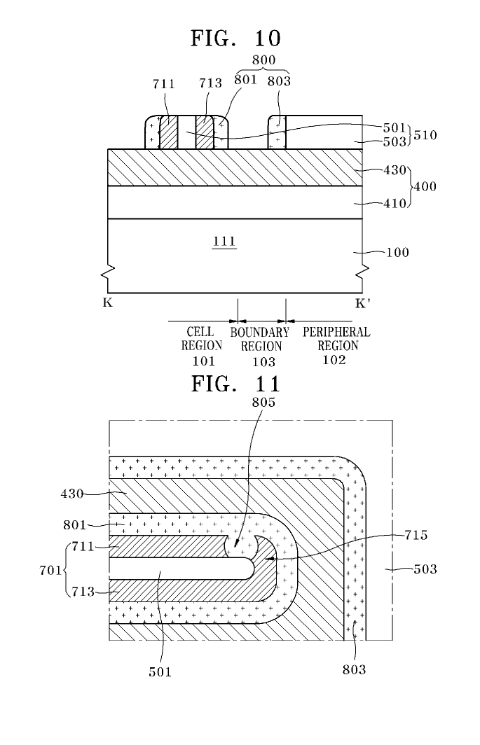

Referring to FIGS. 10 and 11, a second spacer 800 is formed on the outer sides of the line patterns 711 and 713 and the side of the second partition pattern 503. The second spacer 800 may be formed of silicon oxide (SiO₂), silicon nitride (Si₃N₄), polysilicon, or other material that has an etch selectivity with respect to the first hard mask layer 400 and the first spacer layer 700. The second spacer 800 may be formed, for example, of the same material as the partition pattern 500.

A first portion 801 of the second spacer 800 is adjacent to the outer side of the line patterns 711 and 713, and has a connection protrusion 805 that fills the division region formed using the hole opening 351. A second portion 803 of the second spacer 800 is adjacent to the side of the second partition pattern 503.

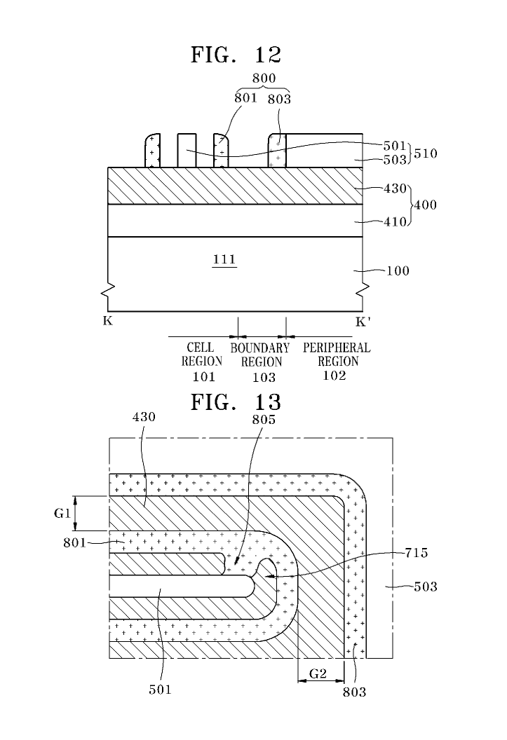

Referring to FIGS. 12 and 13, the line patterns 711 and 713 are selectively removed so that the first partition pattern 501, the second partition pattern 503 and the second spacer 800 selectively expose the first hard mask layer 400 thereunder. The second partition pattern 503 and the second portion 803 of the second spacer 800 cover the peripheral region 102 and provide a cell open pattern exposing the cell region 101. The first partition pattern 501 and the first portion 801 of the second spacer 800 expose a spacer portion for forming a gate trench for a buried gate at a portion of the first active region 111 (FIG. 2) including the line patterns 711 and 713 (FIG. 11). The spacer portion between the first portion 801 of the spacer 800 and the second portion 803 of the second spacer 800 exposes a spacer portion for forming a field trench isolating the first active region 111 by the active region 110 (FIG. 1) at a portion of the first active region 111.

The critical dimension (CD) G1 of the spacer portion for forming the field trench or the CD G2 of a spacing distance from the peripheral region 102 may vary depending on the thickness of the second spacer 800. Therefore, when depositing a second spacer layer for the second spacer 800, by varying the deposition thickness of the second spacer layer, the CD G1 of the spacer portion for forming the field trench or the CD G2 of the spacing distance from the peripheral region 102 may be controlled to control or change the CD of the field trench and the CD of the spacing interval between the peripheral region 102 and the active region 110 (FIG. 1).

Referring to FIGS. 13 and 14, first hard mask patterns 401 and 403 are formed by selectively etching/removing a portion of the first hard mask layer 400 exposed by the first and second partition patterns 501 and 503 and the second spacer 801 and 805. The first hard mask first pattern 401 is formed as a cell pattern in the cell region 101, and the first hard mask second pattern 403 is formed as a peripheral pattern covering the peripheral region 102.

Referring to FIGS. 14 and 15, a portion of the wafer 100 exposed through the first hard mask pattern 401 and 403, for example, a portion of the first active region 111, is selectively etched to form a gate trench 210 for burying the gate 200 in the active region 110, and to form a field trench 123 for dividing the line-shaped first active region 111 (FIG. 2) into active regions 110 as illustrated in FIG. 1. Thereafter, a gate 200 filling the gate trench 210 may be formed together with an oxidation process for forming a gate oxide layer, and then a dielectric layer filling the field trench 123 may be formed. If a conductive layer for the gate 200, for example, a conductive polysilicon layer or a metal (e.g., tungsten (W)) layer remains in the field trench 123 in the process of forming the gate 200, a separate etch mask 203 (FIG. 1) covering the gate 200 may be formed and the conductive layer or the metal layer remaining in the field trench 123 may be removed.

As described above, the fine pattern fabricating method according to an exemplary embodiment of the present invention may include a process of depositing a spacer on the first partition pattern 501 two times to adhere a double-spacer structure, and may selectively remove the end portion of the first spacer first portion 701 adjacent to one of two edges of the end of the first partition pattern 501 before deposition of the second spacer 800 to form the connection protrusion 805 connecting the second spacer 800 to the first partition pattern 501. Accordingly, the spacer portion between the second spacer 800 and the first partition pattern 501 for providing the shape of the buried gate 200 may be provided in an ‘L’ shape having a bent portion 715 at an end thereof. Thus, the end portion 201 of the gate 200 resembling such a shape may have a bent shape to provide the pad portion that has a wider CD than the body of the gate 200. The bent end pad portion has a wide CD, thus making it possible to secure a wider overlay margin of the connection contact connected to the gate.

Also, while providing space portions for providing the shape of the gate 200, by causing the second spacer 800 to have a ring-shaped end connection structure, it is possible to provide the field trench (123 of FIG. 15) that divides, by the space between the second spacer 800 and a nearby second spacer 800, the line-shaped first active region (111 of FIG. 2) into separate active regions (110 of FIG. 1). Accordingly, the active region 110 and the gate 200 having a fine CD size can be implemented, thus making it possible to implement a semiconductor device with a reduced design rule.

As described above, the present invention can fabricate a fine pattern having a pitch that is ⅓ times smaller than the pitch of a partition pattern formed on a wafer through an exposure and etching process. Also, the line patterns having an end portion having a larger CD than the line pattern CD, that is, the line patterns having a pad pattern, for example, L-shaped line patterns are formed to oppose each other. Two neighbor line patterns are isolated from each other at the line end. Two line patterns disposed at both sides of the isolated two line patterns are formed such that the line ends are connected to each other.

The embodiments of the present invention have been disclosed above for illustrative purposes. Those skilled in the art will appreciate that various modifications, additions, and substitutions are possible without departing from the scope and spirit of the invention as disclosed in the accompanying claims.

What is claimed is:

1. A method for fabricating a fine pattern, comprising:
forming a line-shaped partition pattern on an underlayer;
adhering a first spacer to a side of the partition pattern;
dividing the first spacer into two line patterns where one line pattern has a bent end by selectively etching a division region in the first spacer;
adhering a second spacer, which has a connection protrusion filling the division region and connecting to the partition pattern, to outer sides of the two line patterns; and
selectively removing the two line patterns.

2. The method of claim 1, wherein the partition pattern comprises a photoresist pattern, and
the second spacer is formed of a material having an etch selectivity with respect to the first spacer, and comprises at least one of silicon oxide (SiO₂), silicon nitride (Si₃N₄), and polysilicon.

3. The method of claim 1, wherein the second spacer is formed of the same material as the partition pattern, and comprises at least one of silicon oxide (SiO₂), silicon nitride (Si₃N₄), polysilicon, and other material that has an etch selectivity with respect to the first spacer.

4. The method of claim 1, wherein the underlayer portion exposed by the selective removal of the two line patterns is selectively etched to form a hard mask pattern.

5. The method of claim 4, wherein the underlayer is formed to have a single-layer structure or a double-layer structure comprising at least one of carbon, silicon oxide (SiO₂), silicon nitride (Si₃N₄), polysilicon, and other material that has an etch selectivity with respect to the second spacer, the partition pattern, and the first spacer.

6. A method for fabricating a fine pattern, comprising:
forming a first field region, which defines active regions extending in a first direction, in a cell region of a wafer comprising the cell region and a peripheral region;
forming a hard mask layer on the wafer;
forming a line-shaped first partition pattern extending in a second direction crossing the first direction and a second partition pattern covering the peripheral region, on the cell region on the hard mask layer;
adhering a first spacer to a side of the first and second partition patterns;
dividing the first spacer into two line patterns where one line pattern has a bent end by selectively etching a division region in the first spacer;
adhering a second spacer, which has a connection protrusion filling the division region and connecting to the first partition pattern, to outer sides of the two line patterns;
selectively removing the two line patterns;
forming a hard mask pattern by selectively removing the hard mask layer portion exposed by the first and second partition patterns and the second spacer; and
selectively etching a portion of the active region exposed through the hard mask pattern to form a gate trench for a buried gate at the active region in which the two line patterns are located, and to form a field trench isolating the active region located at the exposed portion of the outside of the second spacer.

7. The method of claim 6, wherein the first and second partition patterns comprise a photoresist pattern, and
the second spacer is formed of a material having an etch selectivity with respect to the first spacer, and comprises at least one of silicon oxide (SiO₂), silicon nitride (Si₃N₄), and polysilicon.

8. The method of claim 6, wherein the first partition pattern comprises a line pattern extending in the second direction that crosses the first direction.

9. The method of claim 6, wherein the second spacer is formed of the same material as the partition pattern, and comprises at least one of silicon oxide (SiO₂), silicon nitride (Si₃N₄), polysilicon, and other material that has an etch selectivity with respect to the first spacer.

10. The method of claim 6, wherein the hard mask layer is formed to have a single-layer structure or a double-layer structure comprising at least one of carbon, silicon oxide (SiO₂), silicon nitride (Si₃N₄), a polysilicon, and other material that has an etch selectivity with respect to the second spacer, the first partition pattern, and the first spacer.

11. The method of claim 6, wherein the adhering of the first spacer to the side of the first and second partition patterns comprises:
depositing a first spacer layer covering the first and second partition patterns; and
anisotropically etching the first spacer layer,
wherein the critical dimension of the field trench depends on the deposition thickness of the first spacer layer.

12. The method of claim 6, wherein the dividing of the first spacer into the two line patterns comprises:
forming an etch mask pattern comprising a hole opening that selectively exposes the first spacer portion adjacent to one of the two edges of the end of the first partition pattern, and a line opening that selectively exposes the first spacer portion adhered to the side of the second partition pattern; and
selectively removing the first spacer portion exposed through the etch mask pattern.
